(19) United States
(12) Patent Application Publication
(10) Pub. No.: US 2006/0022661 A1
(43) Pub. Date: Feb. 2, 2006

(54) Circuit arrangement for a microcontroller and method of operating a remote control receiver

(75) Inventors: Carsten Deppe, Aachen (DE); Matthias Wendt, Wurselen (DE)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V.

(21) Appl. No.: 10/533,751

(22) PCT Filed: Oct. 23, 2003
(86) PCT No.: PCT/IB03/04695

§ 371 Date: May 4, 2005

(30) Foreign Application Priority Data
Nov. 7, 2002 (DE) 102518068

(51) Int. Cl. G01R 19/00

(52) U.S. Cl. 324/67

(57) ABSTRACT

A circuit arrangement is described for a microcontroller having an improved energy consumption which is achieved in that the microcontroller (2) is connected to its operating clock only during evaluation of a signal. A switching means (5) through-connecting the operating clock when a “logic 1”, signal is present at the control input is arranged between the microcontroller (2) and the clock generator (6). This “logic 1” signal is generated by setting a flip-flop (4, 7) for example, when receiving a remote control signal. The program run of the microcontroller (2) is stopped at a defined breakpoint so that there is no transient time.

The invention relates to a circuit arrangement for a microcontroller which is assigned to a battery-operated, possibly portable apparatus and/or an apparatus being electrically powered by the mains. The microcontroller is to be operated while saving energy.

The invention also relates to a remote control receiver for wireless reception of remote control signals, which receiver should have an improved energy consumption. The standby situation of the remote control receiver leads to a discharge of the battery and hence to a time-limited possibility of using the battery or to increased operating costs due to constant consumption of energy from the mains, also beyond the actual operation of the apparatus.

Such a system for wireless reception of remote control signals can be realized with RF, ultrasound or infrared techniques. An essential part of the current required by the remote control receiver in standby operation, i.e. when it is ready for reception, is caused by the signal receiver and the signal decoder. This current consumption limits the possible minimal energy consumption or leads to a shorter lifetime of the battery. Reception and decoding are generally performed by two components in a circuit arrangement for wireless reception of control signals: a receiving module and a microcontroller. The receiving module may be directly connected to the microcontroller. This microcontroller operates continually while signals of the receiving module trigger an interrupt. When the microcontroller changes to the sleep mode in the period between which two signals are processed, the current consumption is reduced to a range of several microamperes, but the processing operation is also delayed in the case of wake-up by the activation signal of the receiving module. The activation signal is generated when an (encoded) remote control signal of the assigned remote control transmitter is received. Consequently, it is not possible to completely capture the first transmitted code of the remote control transmitter. Essential causes for the current consumption in the microcontroller are its operating frequency and the number of elements which must switch at this operating frequency. For example, an IR receiving diode with subsequent amplifiers, filters and gain control loops is integrated in the receiving module. At the output, this receiving module supplies a binary signal which can be directly connected to the microcontroller or a decoding component. In the standard embodiment, such receiving modules have a typical current consumption of up to 5 mA, and as from 0.2 mA for the latest current-saving versions. In the state of the art described here, the microcontroller only becomes active at an input signal of the receiving component.

An energy-saving method for the wireless reception of carrier signal-modulated data is known from DE 100 54 529 A1. In this method, the circuit components of the receiving module are divided into a group being intermittently supplied with electrical energy and a group being fed uninterruptedly. This document does not describe the microcontroller or the decoding operation in general.

EP 0 663 733 A1 relates to a remote control for an electrically operated apparatus which is reconnected to the mains via a supply switch when it is reactivated. The supply switch is activated by an evaluation circuit in dependence upon the control signals of a receiving section. A battery-fed circuit arrangement indirectly controls the interval switch. The interval switch is controlled by a clock generator and intermittently connects the receiving section to the power supply circuit during the standby period of the receiver. When the receiving section receives at least a part of a starting signal detected by the evaluation circuit, the clock generator is driven in the sense of a permanent closure of the interval switch during the period of the subsequent control signal transmission. The control signals transmitted subsequent to the starting signal can then be received in the conventional manner and utilized for controlling the apparatus which is put into operation by first connecting it to the mains via the supply switch. The remote control described in this document has the drawback that the remote control signal which is received must have a code for a given starting signal.

It is therefore an object of the invention to provide a circuit arrangement for a microcontroller which is alternately active or in its sleep mode, which circuit arrangement has a low energy consumption during the sleep mode of the microcontroller. It is a further object of the invention to provide a method of operating such a microcontroller. Moreover, it is an object of the invention to provide a remote control receiver which has a low energy consumption in the standby mode and can be used for conventional remote control codes.

According to the invention, the object is solved by a circuit arrangement for a microcontroller which is directly or indirectly connected at the input to a module generating an output signal and can be connected to a clock generator for the purpose of supply with its operating frequency. The circuit arrangement comprises a switching means between the clock generator and the microcontroller, while the signal input of the switching means is connected to the clock generator, the control input of the switching means is directly or indirectly connected to the module generating an output signal, and the output is connected to the microcontroller.

Whenever the clock generator is connected to the microcontroller, this microcontroller will acquire its operating frequency and operates continuously. The microcontroller consumes energy drawn from its power supply voltage. By arranging a switching means in between, the microcontroller can be separated from its operating frequency without switching off the clock generator. The clock generator, for example, an oscillator requires a certain transient time when it is switched on. The resultant delay in the signal processing operation is avoided in the circuit arrangement according to the invention because the clock generator itself is not switched off.

It is advantageous that an analyzer is arranged between the module generating an output signal and the switching means, so that erroneous switching due to short interference pulses is prevented. The analyzer detects whether the received signal is a useful signal or interference. In the simplest case, for example, an arrangement of two resistors, one diode, one capacitor and one Schmitt trigger component is used for this purpose. The output signal charges the capacitor via the first resistor and, after a short delay time, the Schmitt trigger is switched. When the signal Snout is interrupted within this short period of time, the capacitor is quickly discharged via the two resistors. In this way, short and interfered signals can be suppressed. The exact design of the analyzer depends on the specification of the output signal.

It is advantageous to buffer the output signal reactivating the microcontroller. To achieve this, one embodiment of the invention has the output signal of the module connected directly or indirectly to the set input of an SR flip-flop and the output of the SR flip-flop is connected to the control input of the switching means. The reset input is directly or indirectly connected to an output of the microcontroller so that the SR flip-flop is reset in a program-controlled manner. Due to this arrangement, the output of the flip-flop becomes “logic 1” when receiving the first control signal after deactivation of the microcontroller. This “logic 1” signal quasi-through-connects the switching means and connects the signal of the clock generator to the microcontroller. Consequently, the microcontroller obtains its operating frequency as soon as a remote control signal is received in order that this signal can be processed correctly. The microcontroller itself generates a reset signal which is applied to the reset input of the SR flip-flop so that the output signal of the flip-flop is set to “logic 0”. Thereupon, the switching means is blocked and the microcontroller is separated from its operating frequency. The clock is thus deactivated at a defined instant which is controlled by the microcontroller itself. The deactivation of the clock is first performed at a predetermined point in the microcontroller program so that the continuation of the program after applying the clock starts at the correct point again.

In a further embodiment of the invention, the output signal is buffered by a JK flip-flop. In this circuit arrangement according to the invention, a first JK flip-flop is arranged between the module generating the output signal and the switching means, and a second JK flip-flop is arranged between the microcontroller and the K input of the first JK flip-flop. It is thereby achieved that both the output signal used as wake-up signal and the reset signal generated by the microcontroller itself are first buffered and then through-connected with the exact clock. Too short or false clock pulses, which might disturb the flawless operation of the microcontroller, are prevented by the first JK flip-flop. Consequently, the clock is always switched on or off at the next complete period. The clock is always exactly switched off in the next-but-one cycle by the second JK flip-flop, after the stop signal has been set, so that the processor adequately gains time to assume its definite rest position and reset the stop signal again.

A further advantage of the circuit arrangement according to the invention for a microcontroller is that the continuing clock can also be used for a time counter which is connected, possibly together with the divider in between, to the clock generator. The remote control receiver can thus also be used in an apparatus which is disconnected from the mains in the switched-off state, but in which a clock should continue. The microcontroller and the time counter may share one part of the circuit arrangement and thus save costs, energy and space.

It is advantageous when an oscillator or a low-frequency quartz generator, i.e. of about 30 to 300 kHz is used as a clock generator, because the low frequency allows a very simple and inexpensive realization of a circuit arrangement which is exact at one clock cycle. By synchronization with the clock, unwanted switching points are avoided. Oscillators of a lower frequency require a relatively small amount of current so that the energy consumption of the overall circuit arrangement is minimized although the clock generator continues to operate without interruption. When the circuit arrangement according to the invention is used in a remote control receiver, this relatively low frequency should be chosen to be high enough for decoding the remote control signal.

In a very simple and inexpensive variant of the invention, the switching means of the circuit arrangement is an AND gate.

As regards the remote control receiver, the object of the invention is solved by a remote control receiver comprising a receiving module for receiving an encoded remote control signal, wherein the receiving module is directly or indirectly connected to a microcontroller for decoding, and the microcontroller can be connected to a clock generator for the purpose of supply with its operating frequency. The remote control receiver comprises switching means having a signal input and a control input between the clock generator and the microcontroller, while the signal input of the switching means is connected to the clock generator, the control input is directly or indirectly connected to the remote control module, and the output is connected to the microcontroller. When a remote control signal or also an interfering secondary light (for example, of fluorescent lamps or electronic energy-saving lamps) is received, the receiving module generates an output signal which is applied to the microcontroller for the purpose of decoding, but also to the switching means for the purpose of reactivation. The output signal generated by the receiving module is thus not only a data carrier but, according to the invention, it is also an activation signal because the fact of its occurrence is utilized to activate (wake up) the microcontroller. However, given conditions may be imposed on the wake-up signal, for example, a given form or a given minimum level in order that the possibility of mistaking it for secondary light is excluded. An appropriate analyzer may be used for this purpose.

The microcontroller is to be reactivated when the receiving module detects a remote control signal. To this end, the control input of the switching means is preferably connected directly or indirectly to the output of the receiving module. When a remote control signal is received, the receiving module supplies an output signal which is applied both to the microcontroller and to the switching means. When both inputs, signal and control input, of the switching means are connected to a “logic 1” signal, the clock of the clock generator is through-connected and the microcontroller is thereby reactivated. Since the clock generator itself was not switched off and the microcontroller was previously stopped at an exactly known position in the program run, there is no transient time and the microcontroller can immediately operate correctly, while the output signal of the receiving module is completely processed.

According to the invention, the object is also solved by a method of operating a microcontroller which can be connected to a clock generator for the purpose of supply with its operating frequency, and in which the program run of the microcontroller determines its switch-off instant (change into the sleep mode) and the output signal of a module brings about the reactivation of the microcontroller. The change into the standby mode is thus realized by the software of the microcontroller and the reactivation by the hardware of the circuit arrangement, namely when an output signal of the input module occurs.

The preferred embodiment is a method of operating a remote control receiver comprising a receiving module at the input for receiving an encoded remote control signal, wherein the receiving module is directly or indirectly connected to a microcontroller for decoding, and the microcontroller can be connected to a clock generator for the purpose of supply with its operating frequency. The clock generator is connected to the microcontroller when the receiving module detects an input signal and thereupon generates an output signal for the microcontroller. This output signal is additionally applied to a flip-flop which is designed in such a way that it generates a flip-flop output signal when it receives the output signal of the receiving module, said flip-flop output signal being applied to the control input of a switching means and thereby through-connecting said switching means and supplying the microcontroller with an operating clock. The remote control receiver may belong to, for example, an electronic apparatus which should have a low energy consumption during standby because it is battery-operated (separated from the mains) or connected to the mains and, for this very reason, should be current-saving.

In a variant on the invention, an additional, activatable clock generator of a higher frequency is through-connected as a clock generator for the microcontroller as soon as it has reached its nominal frequency. Reaching the nominal frequency of the second clock generator, for example, an RC oscillator may be determined by means of a counting circuit and the first clock generator. When it is not needed, the additional clock generator is switched off for the purpose of saving energy. It is started again when the receiving module detects a remote control signal and thereupon generates an output signal for the microcontroller. The first clock generator having the low frequency is timely connected to the microcontroller so that there is no loss of information when evaluating the received signal. The high clock frequency is then through-connected with a minimal delay.

The remote control receiver according to the invention provides further saving of energy with a minimal number of components. Since there is no time delay during the evaluation, there is neither any loss of information.

The microcontroller of the remote control receiver according to the invention controls the instant of its deactivation (sleep mode) itself. At a predetermined point in the program, the microcontroller generates a reset signal for the flip-flop so that the switching means separates the clock generator from the microcontroller. The invention thus relates to a method of saving energy, at which the transfer to the sleep mode is programmable in the microcontroller and at which the output signal generated by a corresponding device causes the microcontroller to be activated.

The embodiments of the invention have in common that the microcontroller is deactivated (sleep mode), and thus consumes less energy, but the clock generator continues to operate so that this does not lead to loss of data due to a delayed switching on when reactivating (waking up) the microcontroller.

These and other aspects of the invention are apparent from and will be elucidated with reference to the embodiments described hereinafter.

In the drawings:

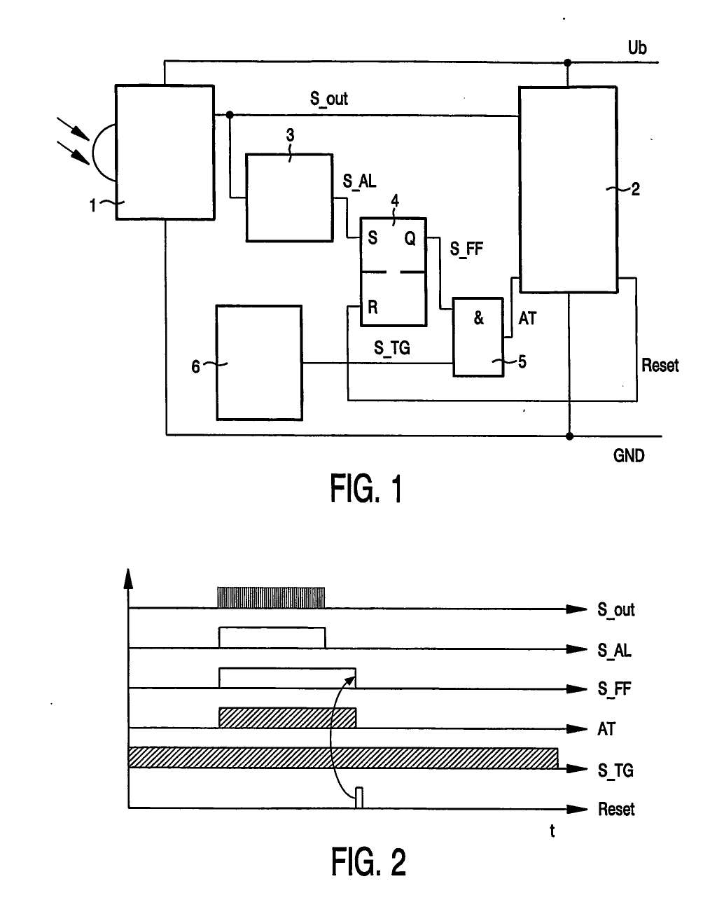

FIG. 1 is a block diagram of a first variant of the remote control receiver according to the invention,

FIG. 2 is a signal diagram of the first variant,

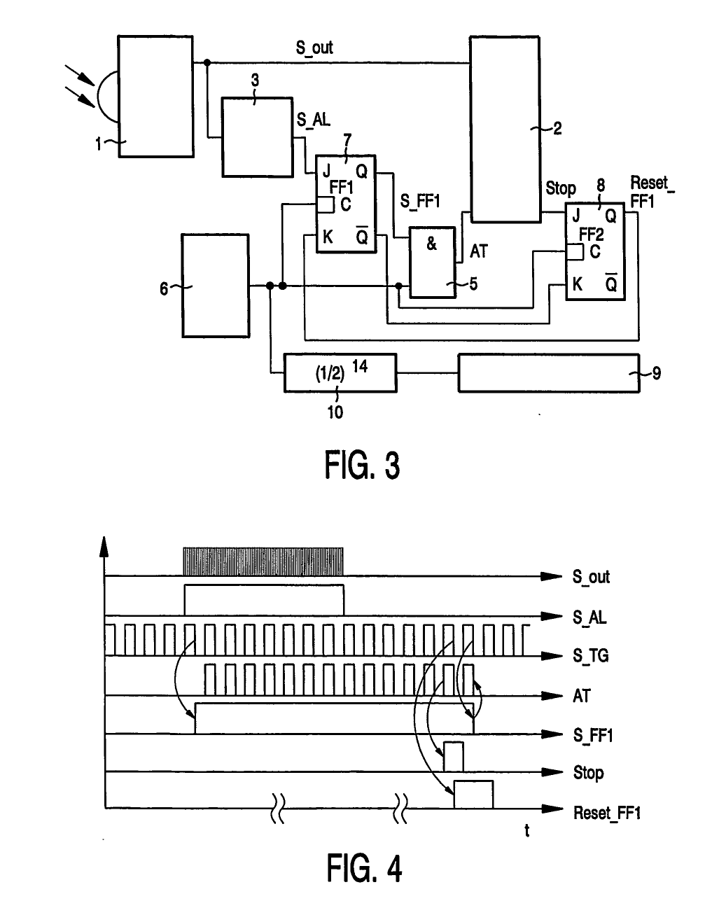

FIG. 3 is a block diagram of a second variant of the remote control receiver according to the invention,

FIG. 4 is a signal diagram of the second variant, and

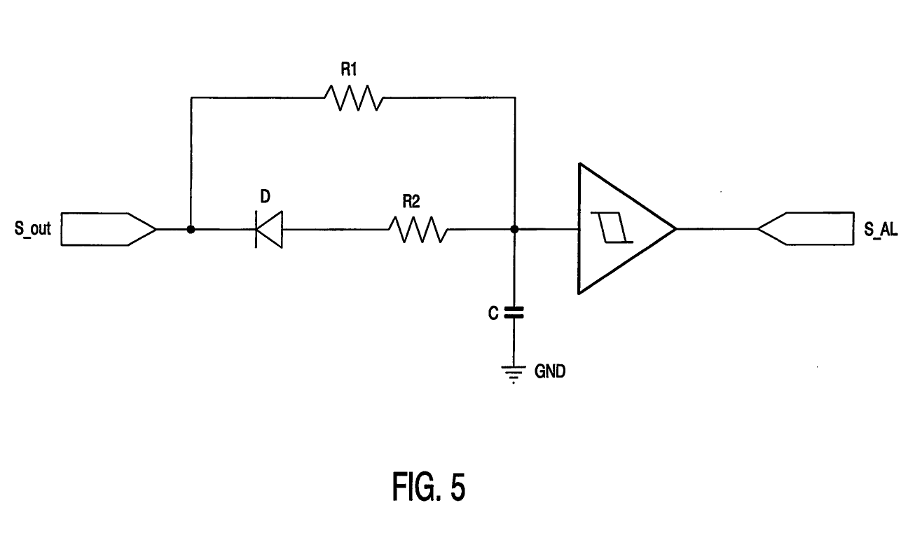

FIG. 5 shows an example of an analyzer.

FIG. 1 is a block diagram of a first variant of the remote control receiver according to the invention. An AND gate is used as switching means 5. The remote control signal is received by a receiving module 1 and converted into an output signal S_out. The output signal S_out is applied both to the microcontroller 2 for the purpose of decoding and to an analyzer 3 which prevents erroneous circuits due to short interference pulses. The output of the analyzer 3 is connected to the S input of an SR flip-flop 4 so that the Q output is set when a remote control signal is received. The Q output is connected to the control input of an AND gate 5 and its signal input is connected to a clock generator 6. The clock generator 6 continues to operate and is connected to the microcontroller 2 when the SR flip-flop 4 has been set. The clock generator 6 is separated from the microcontroller 2 again when the microcontroller 2 applies a “logic 1” signal to the R input of the SR flip-flop 4 via its connection to this R input. Consequently, the Q output of the SR flip-flop 4 is set to “logic 0”, so that the subsequent AND gate 5 is disabled. The power supply voltage Ub is shown for the receiving module 1 and the microcontroller 2.

FIG. 2 is a signal diagram of the first variant of the remote control receiver. The output signal S_out of the receiving module 1 is an encoded signal which consists of a plurality of pulses and is converted into a continuous “logic 1” signal SEAL by the analyzer 3. The clock generator 6 continuously produces its output signal S_TG. The operating clock AT is applied to the microcontroller 2 only when the output signal S_FF of the flip-flop 4 is “logic 1”. This microcontroller evaluates the output signal S_out of the receiving module 1. When the evaluation has ended and when there is no further signal, the microcontroller 2 continues to operate until a predetermined breakpoint in the program. At this point, a reset signal is generated for the SR flip-flop 4 so that the clock is separated again from the microcontroller 2.

FIG. 3 is a block diagram of a second variant of the remote control receiver according to the invention, which prevents interference in the evaluation in the microcontroller 2 due to too short or equal clock pulses. In this variant, the output signal S_AL of the analyzer 3 is applied to the J input of a first JK flip-flop 7. The clock input of the first flip-flop 7 is connected to the clock generator 6. When a remote control signal is received, the output signal S_AL of the analyzer 3 becomes “logic 1”. As soon as a negative clock pulse is subsequently present at the clock input, the Q output is set to “logic 1”. This output signal S_FF1 is applied to the AND gate 5 so that the operating clock AT is applied to the microcontroller 2 in the first complete period as from the beginning of the remote control signal. After the output signal S_out of the receiving module 1 has been decoded and when there is no further output signal, the microcontroller 2 applies a stop signal to the J input of a second JK flip-flop 8 during the penultimate clock cycle before its deactivation. This “logic 1” signal is further applied as a reset signal Reset_FF1 to the K input of the first JK flip-flop 7, with the falling edge of the next clock of the clock generator 6 at the Q output. The stop signal starts with a positive edge of the operating clock AT and covers exactly one period of the operating clock AT. It is thereby ensured that, of two consecutive pulses of the operating clock AT, the first negative edge is used for generating the reset signal Reset_FF1 and the second negative edge is used for resetting the first JK flip-flop 7, so that the AND gate 5 again separates the microcontroller 2 from the clock generator 6 and the second JK flip-flop 8 is reset by the first JK flip-flop via the Q output in the next clock cycle. In this embodiment, a time counter 9 is additionally operated by the clock generator 6, with a divider 10 being arranged in between, which transforms the frequency of the clock generator 6 to the frequency required by the time counter 9. The joint usage of the clock generator 6 by the decoding device and the time counter 9 leads to savings of energy and space. The fixed (hardware) realization of the time counter provides the possibility, after the apparatus has been switched on again, of regaining the clock time or the time that has elapsed, so that this function can be fulfilled completely without the microcontroller.

FIG. 4 is a signal diagram of the second variant of the remote control receiver according to the invention. When the receiving module 1 detects an input signal, it generates an appropriately encoded output signal S_out. The analyzer 3 converts the encoded signal into a continuous “logic 1” signal S_AL. The clock generator 6 continuously produces its clocked output signal S_TG. This signal is applied as operating clock AT to the microcontroller 2 only when the output signal S_AL of the analyzer 3 is “logic 1” and the next negative edge of the clock occurs. The microcontroller 2 is separated at the exact clock with a falling edge from its operating clock AT when the stop signal generated by the program is through-connected to the second JK flip-flop 8 and is present as reset signal Reset_FF1 at the K input of the flip-flop 7. The program of the microcontroller is implemented in such a way that the stop signal has already been reset at this instant. In the next clock cycle, the buffered stop signal Reset_FF1 is also reset again.

FIG. 5 shows an example of an analyzer. Behind the input for the output signal S_out, a first resistor R1 is arranged parallel to a diode D with a second resistor R2. The output signal S_AL is generated by a Schmitt trigger. The output signal S_out charges a capacitor C via the first resistor R1, and the Schmitt trigger is switched after a short delay time. When the output signal S_out is interrupted within this short delay time, the capacitor C is rapidly discharged via both resistors R1, R2.

1. A circuit arrangement for a microcontroller (2) which is directly or indirectly connected at the input to a module generating an output signal (S_out) and can be connected to a clock generator for the purpose of supply with its operating frequency, characterized in that the circuit arrangement comprises a switching means (5) between the clock generator (6) and the microcontroller (2), in that the signal input of the switching means (5) is connected to the clock generator (6), the control input of the switching means (5) is directly or indirectly connected to the module generating an output signal, and the output is connected to the microcontroller (2).

2. A circuit arrangement as claimed in claim 1, characterized in that an analyzer (3) is arranged between the module generating an output signal (S_out) and the switching means (5).

3. A circuit arrangement as claimed in claim 1, characterized in that the output signal of the module is directly or indirectly applied to the set input of an SR flip-flop (4), the output of the SR flip-flop (4) is connected to the control input of the switching means (5), and the reset input is directly or indirectly connected to an output of the microcontroller (2).

4. A circuit arrangement as claimed in claim 1, characterized in that a first JK flip-flop (7) is arranged between the module generating the output signal (S_out) and the switching means (5), and a second JK flip-flop (8) is arranged between the microcontroller (2) and the K input of the first JK flip-flop (7).

5. A circuit arrangement as claimed in claim 1, characterized in that a time counter (9) is connected to the clock generator (6).

6. A circuit arrangement as claimed in claim 1, characterized in that the clock generator (6) is an oscillator or a low-frequency quartz generator.

7. A circuit arrangement as claimed in claim 1, characterized in that the switching means is an AND gate.

8. A remote control receiver comprising a receiving module for receiving an encoded remote control signal, wherein the receiving module is directly or indirectly connected to a microcontroller for decoding, and the microcontroller can be connected to a clock generator for the purpose of supply with its operating frequency, characterized in that the remote control receiver comprises switching means having a signal input and a control input between the clock generator and the microcontroller, in that the signal input of the switching means is connected to the clock generator, the control input is directly or indirectly connected to the remote control module, and the output is connected to the microcontroller.

9. A method of operating a microcontroller which can be connected to a clock generator for the purpose of supply with its operating frequency, characterized in that the program run of the microcontroller determines its switch-off instant (change into the sleep mode), and the output signal (S_out) brings about the reactivation of the microcontroller.

10. A method of operating a remote control receiver comprising a receiving module (1) for receiving an encoded remote control signal, wherein the receiving module (1) is directly or indirectly connected to a microcontroller (2) for decoding, and the microcontroller (2) can be connected to a clock generator (6) for the purpose of supply with its operating frequency, characterized in that the clock generator (6) is connected to the microcontroller (2) when the receiving module (1) detects an input signal and thereupon generates an output signal (S_out) for the microcontroller (2), and in that this output signal (S_out) is additionally applied to a flip-flop (4, 7) which is designed in such a way that it generates a flip-flop output signal (S_FF) when it receives the output signal (S_out) of the receiving module (1), said flip-flop output signal (S_FF) being applied to the control input of a switching means (5) and thereby through-connecting said switching means and supplying the microcontroller (2) with an operating clock (AT).

11. A method as claimed in claim 10, characterized in that an additional, activatable clock generator of a higher frequency is through-connected as a clock generator for the microcontroller (2) as soon as the additional, activatable clock generator has reached its nominal frequency.
